(19) United States
(12) Patent Application Publication
(10) Pub. No.: US 2007/0297151 A1
(43) Pub. Date: Dec. 27, 2007

(54) Compliant conductive interconnects

(76) Inventors: Larry E. Mosley, Santa Clara, CA (US); James G. Maveety, San Jose, CA (US); Fay Hua, San Jose, CA (US)

Correspondence Address: TROP PRUNER & HU, PC, 1616 S. VOSS ROAD, SUITE 750, HOUSTON, TX, 77057-2631, US

(21) Appl. No.: 11/475,528

(22) Filed: Jun. 27, 2006

(51) Int. Cl. H05K 7/00; H01L 21/44

(52) U.S. Cl. 361/748; 438/612

(57) ABSTRACT

An integrated circuit including an interlayer dielectric which may be prone to failure due to processing conditions may be protected by coupling the integrated circuit to a substrate through a solder ball over a conductive polymer. The conductive polymer allows conduction of electrical current to or from the integrated circuit and also provides cushioning against stresses including both mechanical perturbations and thermal expansion and contraction. As a result, relatively lower dielectric constant materials may be utilized as interlayer dielectrics within the integrated circuit.

### BACKGROUND

This relates to an interconnect to attach a die to a package.

Often times when a die is secured to an organic substrate, during the attachment assembly process, interlayer dielectrics (ILD) in the die may tend to crack. Such cracking is due to the fact that lower dielectric constant interlayer dielectrics are mechanically weaker than most conventional ILD materials.

Specifically, current flip chip technology uses solder joints to provide mechanical and electrical connection between the substrate and a silicon die. One of the most severe stress conditions occurs during the chip attach process. The stress results from the coefficient of expansion mismatching conditions between the substrate and the silicon die. The silicon, pad material, and substrate materials are much stronger than the interlayer dielectric that is inside the die.

During the chip attach process, the stress created from the coefficient of thermal expansion mismatching of die and substrate during temperature change and the elevated temperatures required for soldering is transferred through the solder joint and directly into the die. Since the interlayer dielectric is the weakest material within the die, it may be damaged.

### BRIEF DESCRIPTION OF THE DRAWINGS

FIG. 1 is an enlarged, partial view of one embodiment of the present invention;

FIG. 2 is an enlarged, partial view of another embodiment of the present invention;

FIG. 3 is an enlarged, partial view of another embodiment of the present invention; and

FIG. 4 is a system depiction in accordance with one embodiment of the present invention.

### DETAILED DESCRIPTION

In accordance with some embodiments of the present invention, a conductive polymer may be used as part of the interconnect to attach a die to a package. The conductive polymer can be used on either the package or the die. The conductive polymer may be sufficiently flexible to reduce stress in interlayer dielectric layers within the die.

As used herein, a conductive polymer is a polymer that has a conductivity of at least above 1E6 Siemens per meter (S/m) or no more than one to two orders of magnitude more resistive than copper. Examples of conductive polymers include organic polymers, copolymers, and conjugated polymers. Specific examples includes polyaniline, polypyrrole, polythiophenes (polyethylenedioxythiophene, and poly(3 hexylthiophene)), poly (p-phenylene vinylene), polyacetylene, poly(fluorene) polynaphthalene and poly(p-phenylenesulfide).

In some embodiments, conductive or nonconductive polymers may be made conductive or more conductive by inserting conductive additives such as carbon particles or metallic fibers, such as copper or silver fibers. In many cases, organic conductive polymers have delocalized conduction bands, often including aromatic units that create a band structure without localized state. Charge carriers having been introduced into conduction or valence bands dramatically increase conductivity.

In accordance with some embodiments of the present invention, desirable conductive polymers may have a deflection greater than 7 mm./N normal to their surface and greater than 10 mm./N in a tangential direction.

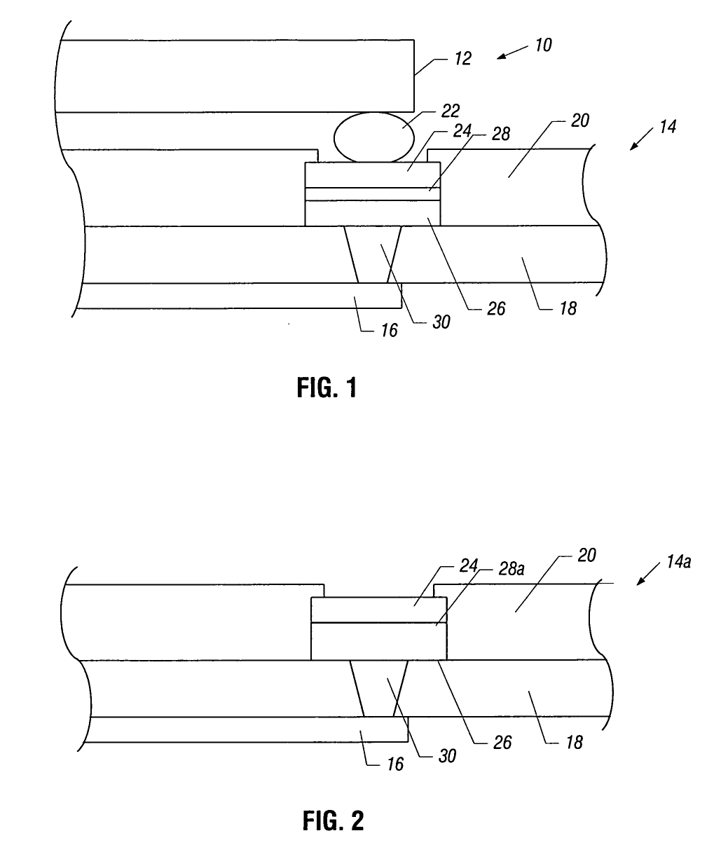

Referring to FIG. 1, in accordance with one embodiment of the present invention, an integrated circuit or die 12 may be secured to a substrate 14. In one embodiment of the present invention, the integrated circuit 12 is a flip-chip including a solder ball 22 that makes a surface mount connection between the integrated circuit 12 and the substrate 14. A solder resist 20 may surround the contact area.

The substrate 14 may include a lower metallic or copper trace 16 coupled by a vertical electrical connection or via 30 through a dielectric layer 18. The dielectric layer 18, in the vicinity of an electrical path, may be covered with a solder resist 20. An opening through the solder resist provides room for an electrical connection between the trace 16 and the solder ball 22.

In one embodiment of the present invention, a pair of metallic pads 26 and 24 may sandwich an intervening conductive polymer 28. The pads 26 and 24 may be copper in one embodiment of the present invention. In such an embodiment, the via 30 may also be formed of copper, although other materials may also be utilized. The thickness of the conductive polymer 28 may be from about 10 to 50 microns in one embodiment. In some embodiments, the combined resistance of the pads 26, 24 and polymer 28 may be about five milliOhms or less.

As a result of the arrangement shown in FIG. 1, electrical conductivity to the integrated circuit 12 from the trace 16 can be achieved, while at the same time providing a cushioning to the integrated circuit 12. This cushioning arises from the greater flexibility of the conductive polymer 28 relative to metal. This cushioning may protect interlayer dielectrics within the integrated circuit 12 from failing. This may be a result of reducing mechanical loads and from cushioning relative mechanical jostling. The use of a conductive polymer also may allow for relative thermal expansion between the integrated circuit 12 and the substrate 14, in that compression or tension may be absorbed within the polymer 28.

Referring to FIG. 2, in accordance with another embodiment of the present invention, a single metallic pad 24 may be utilized with a conductive polymer 28a which may, in some embodiments, be thicker. In general, the conductive polymer 28 or 28a may be more flexible than the metals conventionally utilized to form the interconnect such as copper.

By using the conductive polymer as part of the interconnect, stress may be reduced in the interlayer dielectric within the integrated circuit. In some embodiments, the conductive polymer does not replace the solder bump, but is merely an additional layer used to reduce stress.

The formation of the polymer 28 or 28a may be done in a variety of different ways. In one embodiment, the polymer may be screen printed. Another alternative is to spin the polymer on and then, using photoresist, remove the polymer from areas where the polymer is not desired. Also, a mask may be used so that the polymer may be deposited and the mask thereafter removed. Other possible techniques include sputtering, dipping, electrophoretic coating, electron beam deposition, spraying, and vacuum deposition.

As another alternative, a monomer that will form the conductor polymer may be mixed with a polymerization catalyst to form a dispersion. One suitable polymerization catalyst is Baytron C catalyst, which is iron III toluene-sulfonate and n-butynol sold by H. C. Starck GmbH, Gostar, Germany. Baytron C catalyst is a commercially available catalyst for Baytron M polymer which is 3, 4-ethylenedioxythiophene, a monomer sold by H. C. Starck GmbH, Gostar, Germany.

Once the catalyst dispersion is formed, various techniques may be utilized to apply the polymer, including any of the techniques described above. In some embodiments, the conductive polymer may be healed or cured. Curing may occur after each application of a conductive polymer layer or may occur after the application of the entire conductive polymer coating. In some embodiments, the conductive polymer may be cured by dipping into an electrolyte solution, such as a solution of phosphoric acid and/or sulfuric acid and thereafter applying a constant voltage to the solution until the current is reduced to a pre-selected level.

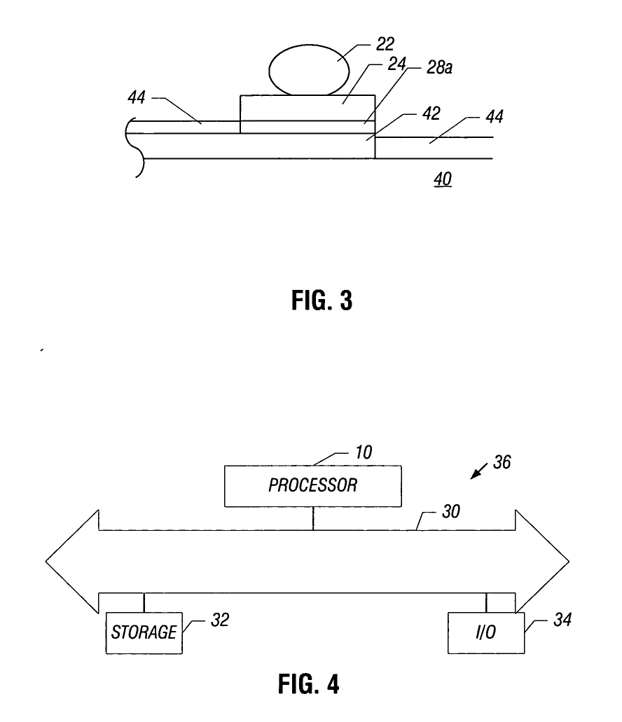

Referring to FIG. 3, a connection to an integrated circuit die 40 may also be made through a compliant conductive polymer 28a as shown in FIG. 3. For example, the compliant conductive polymer 28a may be defined over a conductive trace 42 such as an interconnect or other metal line. A conductive contact or pad 24 may be defined over the polymer 28a and a suitable connection may be made thereto such as through a solder ball 22. Otherwise, other than the fact that the connection is to an integrated circuit die, the previous discussion is equally applicable to this embodiment. A passivation layer 44 may surround the contact area and cover the trace 42. The layer 44 may be less than 10 microns thick in some cases.

Referring to FIG. 4, in accordance with one embodiment of the present invention, the integrated circuit 10 may be a processor, as illustrated, which may be mounted in an electric component 36 such as a computer. The processor may be coupled to a board 30, including a bus, which then electrically couples the processor to other devices, such as a storage 32 and an input/output interface 34.

Thus, the board 30 may correspond to the substrate 14 in some embodiments. In other embodiments, the die may be a processor secured to a substrate through a conductive polymer and the die and substrate may be packaged as an integrated circuit package that is thereafter mounted on a board such as a printed circuit board. However, generally, the substrate 14 may be coupled to the board 30. Other arrangements are also possible. Of course, the configuration of a processor-based system and its application is highly variable. For example, in addition to forming integrated circuits on motherboards or other components, the present invention may be utilized in a variety of integrated circuits, including memory integrated circuits, logic integrated circuits, and communication circuits, to mention a few examples.

Generally, embodiments will have application in situations where surface mounting of an integrated circuit to a board or other substrate is achieved while using relatively low dielectric constant materials that may be prone to cracking due to the coefficient of thermal expansion mismatching, jostling, and application of heat in processing the integrated circuit and the board.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
electrically coupling an integrated circuit having a solder ball to a substrate through a conductive polymer.

2. The method of claim 1 including providing the conductive polymer on a substrate.

3. The method of claim 2 including coupling said integrated circuit to said substrate using said solder ball.

4. The method of claim 3 including providing a metal contact over said conductive polymer, said metal contact contacting said solder ball.

5. The method of claim 4 including providing a metal contact under said conductive polymer.

6. The method of claim 5 including providing a via through said substrate, said via coupled to said solder ball.

7. The method of claim 1 including using a conductive polymer which has a conductive additive.

8. The method of claim 1 including using a conductive polymer formed as a polymer material that is conductive.

9. The method of claim 1 including electrically coupling using a conductive polymer having a conductivity of at least 1E6 S/m.

10. The method of claim 1 including coupling an integrated circuit to a substrate, said integrated circuit including a interlayer dielectric.

11. An interconnect comprising:
a substrate;
a die surface mounted on said substrate by a solder ball; and
said substrate including a conductive polymer over which said solder ball is secured.

12. The interconnect of claim 11 including a metal pad on at least one side of said conductive polymer.

13. The interconnect of claim 11 including a conductive pad on both sides of said polymer.

14. The interconnect of claim 11 including a via and a trace, said via and said trace electrically coupled to said conductive polymer.

15. The interconnect of claim 11 wherein said conductive polymer includes a polymer that is conductive.

16. The interconnect of claim 11 wherein said conductive polymer includes a polymer and material within said polymer to enable electricity to be conducted by said conductive polymer.

17. The interconnect of claim 11 wherein said conductive polymer has a conductivity of at least 1E6 S/m.

18. The interconnect of claim 11 wherein said interconnect is packaged within an integrated circuit package.

19. The interconnect of claim 11 wherein said integrated circuit includes an interlayer dielectric.

20. The interconnect of claim 11 wherein said conductive polymer has a deflection greater than 7 mm, per Newton normal to its surface.

21. A substrate comprising:
a structure;
a metal pad on said structure; and
a conductive polymer between said structure and said metal pad.

22. The substrate of claim 21 wherein said substrate is a printed circuit board.

23. The substrate of claim 21 wherein said substrate is a substrate for an integrated circuit package.

24. The substrate of claim 21 including a metal pad on both sides of said conductive polymer.

25. The substrate of claim 21 including a trace on said structure and a via through said structure, said via coupled to said trace and said conductive polymer.

26. The substrate of claim 21 wherein said conductive polymer has a conductivity of at least 1E6 S/m.

27. The substrate of claim 21 wherein said conductive polymer has a deflection greater than 7 mm, per Newton normal to its surface.

28. The substrate of claim 21 wherein said conductive polymer includes a polymer that is conductive.

29. The substrate of claim 21 wherein said conductive polymer includes a polymer and material within said polymer to enable electricity to be conducted by said conductive polymer.

30. The substrate of claim 21 wherein said substrate is a die.
